(19) United States
(12) Patent Application Publication
(10) Pub. No.: US 2025/0273547 A1
(43) Pub. Date: Aug. 28, 2025

(54) STITCH BOND TO COPPER NANOTWIN PLATED LEAD

(71) Applicant: Texas Instruments Incorporated, Dallas, TX (US)

(72) Inventors: Jomari Austria, Malabon City (PH); Ray Fredric De Asis, Mabalacat (PH); Jeffrey Solas, Iloilo City (PH)

(21) Appl. No.: 18/589,721

(22) Filed: Feb. 28, 2024

(51) Int. Cl. H01L 23/00; H01L 21/768; H01L 23/495

(52) U.S. Cl. CPC H01L 23/49582; H01L 21/2885; H01L 21/4821; H01L 24/48; H01L 24/85; H01L 2224/48106; H01L 2224/48175; H01L 2224/48465

(57) ABSTRACT

An electronic device includes a package structure, a conductive terminal exposed outside the package structure and having a nanotwin plated layer, a semiconductor die in the package structure, and a bond wire enclosed by the package structure and having a first end and a second end, the first end connected to the semiconductor die by a first bond, and the second end connected to the nanotwin plated layer by a second bond. A method includes performing a plating process that forms a nanotwin plated layer on a conductive terminal, and performing a wirebonding process that forms a bond wire having a first end connected to a semiconductor die by a first bond, and a second end connected to the nanotwin plated layer by a second bond.

### BACKGROUND

Low strength connection between a bond wire/stitch bond and a lead frame can adversely affect bondability and reliability. Different wire bonding connection types such as ball bump over stitch bond and stitch bond over ball bump can improve connection strength between a bond wire/stitch bond and a lead frame, but these techniques lengthen the wirebonding process and increase manufacturing cost. Lower cost stitch bonding to prospective leads or other lead frame features can be problematic. Lead frames can be processed by surface etching, stamping and/or cutting to form half etch features to improve mold material adhesion and enhance product reliability. Bare copper to copper (Cu—Cu) bonding can lower manufacturing cost in terms of material cost and significantly reduced lead frame manufacturing time. However, surface granularity increases with reduced roughness, which can cause delamination between a lead frame and mold compound. Moreover, bare Cu—Cu bonding is thermally constrained with higher wirebonding process temperature inducing oxidation, which impacts manufacturability and reliability. Ultrasonic wire bonding can enhance bond strength compared with thermo-compression by increasing copper atom diffusion, but ultrasonic bonding adds cost. Another approach forms a wire bond with a patterned capillary tip instead of a granulated tip to provide more grip on the wire during bonding and mitigate heavy capillary imprint due to wire sliding during bonding, but this also increases manufacturing cost and complexity.

### SUMMARY

In one aspect, an electronic device includes a package structure, a conductive terminal exposed outside the package structure and having a nanotwin plated layer, a semiconductor die in the package structure, and a bond wire enclosed by the package structure. The bond wire has first a first end connected to the semiconductor die by a first bond and a second end connected to the nanotwin plated layer by a second bond.

In another aspect, a system includes a circuit board and an electronic device attached to the circuit board, where the electronic device includes a package structure, a conductive terminal exposed outside the package structure and soldered to a conductive feature of the circuit board. The conductive terminal has a nanotwin plated layer, and the electronic device includes a semiconductor die in the package structure and a bond wire enclosed by the package structure. The bond wire has first a first end connected to the semiconductor die by a first bond and a second end connected to the nanotwin plated layer by a second bond.

In a further aspect, a method of fabricating an electronic device includes performing a plating process that forms a nanotwin plated layer on a conductive terminal and performing a wirebonding process that forms a bond wire having a first end connected to a semiconductor die by a first bond, and a second end connected to the nanotwin plated layer by a second bond.

In another aspect, a lead frame includes a conductive terminal and a nanotwin plated layer on an outer surface of the conductive terminal.

### BRIEF DESCRIPTION OF THE DRAWINGS

FIG. 1 is a top perspective view of an electronic device with bond wires having multiple bonds to nanotwin plated layers of conductive terminals.

FIG. 1A is a sectional side elevation view of the electronic device taken along line 1A-1A of FIG. 1.

FIG. 1B is a partial sectional view of a portion of the nanotwin plated layer.

FIG. 1C is a simplified crystalline structure view of a twin boundary between matrix and twin grains of the nanotwin plated layer.

FIG. 1D shows crystallographic 100, 110, and 111 copper molecule alignments.

FIG. 1E is a simplified crystalline structure view of a grain boundary between non-twinned copper grains.

FIG. 2 is a flow diagram of a method of fabricating an electronic device with an included wirebonding method.

FIG. 2A a is a flow diagram of an example nano twin plating method with optional pulsed plating.

FIG. 2B is a graph of example pulsed nano twin plating process current density.

FIGS. 3-7 are partial side elevation views of the electronic device of FIGS. 1-1C undergoing fabrication processing according to the method of FIGS. 2 and 2A.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. The example structures include layers or materials described as over or on another layer or material, which can be a layer or material directly on and contacting the other layer or material where other materials, such as impurities or artifacts or remnant materials from fabrication processing may be present between the layer or material and the other layer or material. Unless otherwise stated, “about,” “approximately,” or “substantially” preceding a value means +/-10 percent of the stated value. One or more structures, features, aspects, components, etc., may be referred to herein as first, second, third, etc., such as first and second terminals, first, second, and third, wells, etc., for ease of description in connection with a particular drawing, where such are not to be construed as limiting with respect to the claims. Various disclosed structures and methods of the present disclosure may be beneficially applied to an electronic device, manufacturing, and/or operating an electronic device such as an integrated circuit. While such examples may be expected to provide various improvements, no particular result is a requirement of the present disclosure unless explicitly recited in a particular claim.

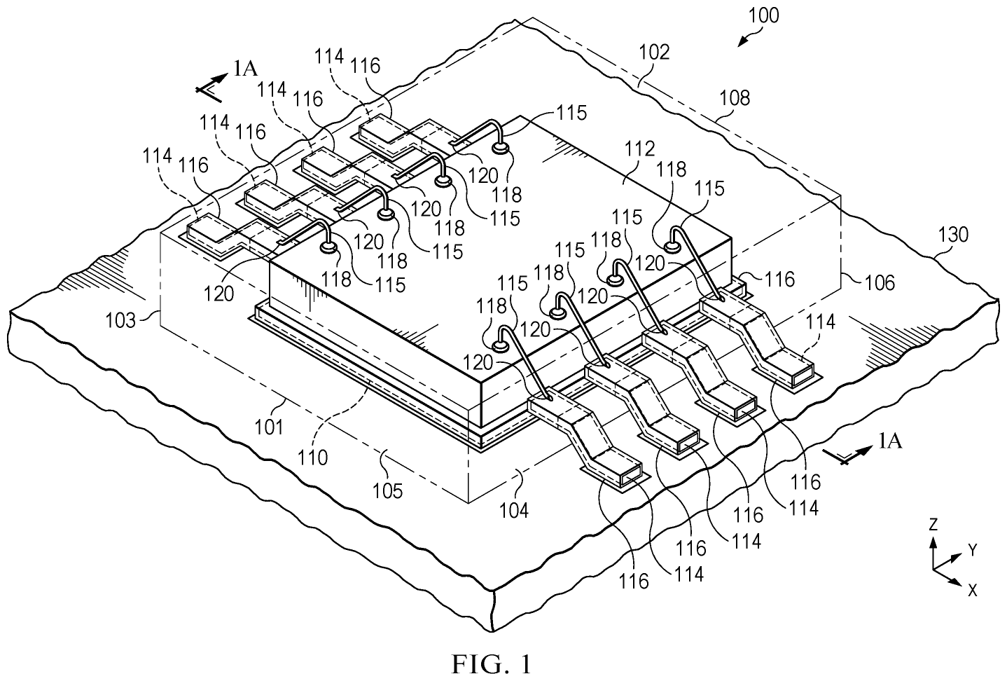

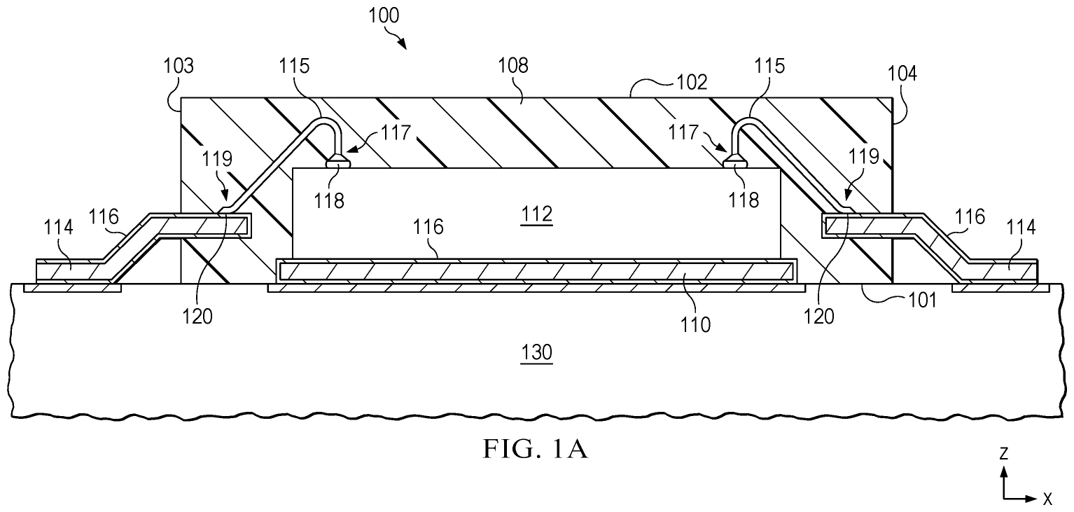

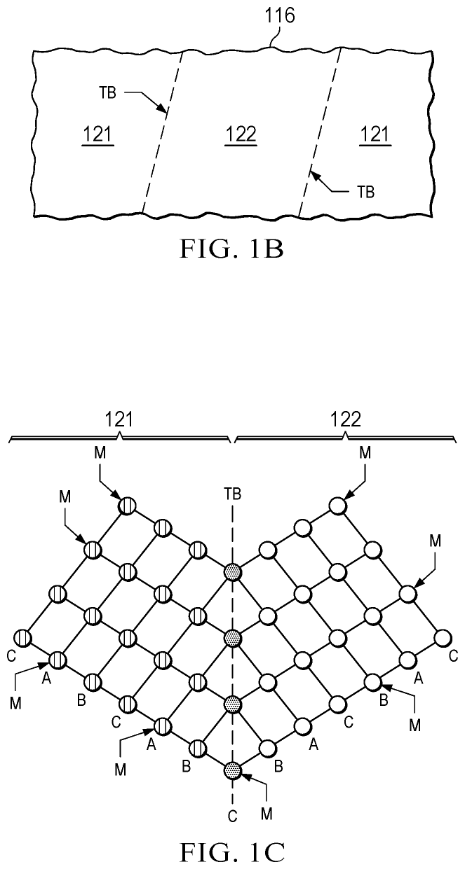

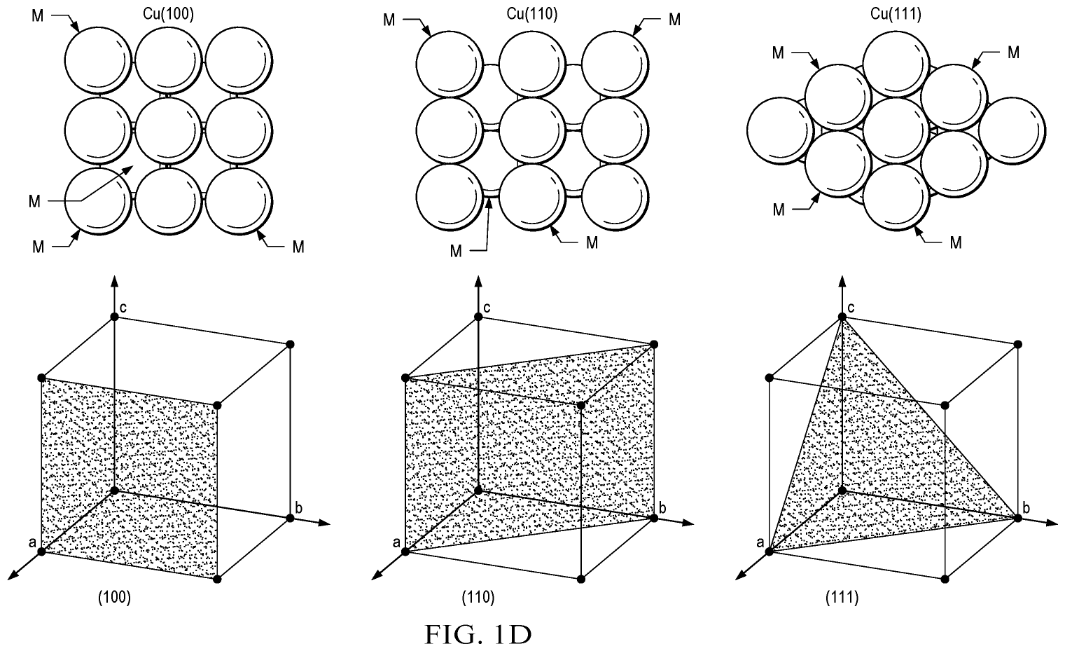

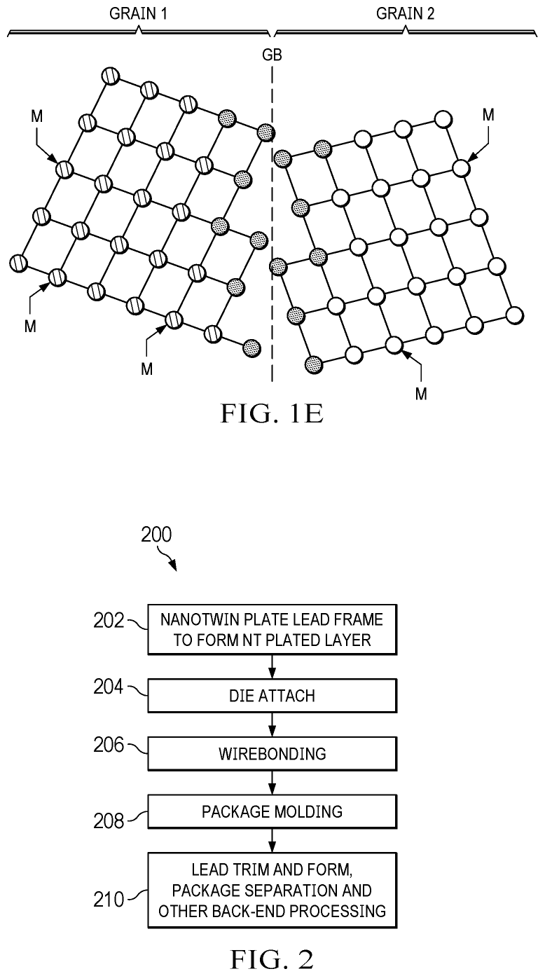

Referring initially to FIGS. 1-1C, FIG. 1 shows an electronic device 100 with bond wires 115 having multiple bonds to nanotwin plated layers 116 of conductive terminals 114 (e.g., leads), FIG. 1A shows a sectional side elevation view of the electronic device 100 taken along line 1A-1A of FIG. 1, FIG. 1B shows a partial sectional view of a portion of the nanotwin plated layer 116, and FIG. 1C shows a simplified crystalline structure view of a twin boundary between matrix and twin grains of the nanotwin plated layer 116. FIGS. 1 and 1A show the electronic device 100 installed in a system, with the electronic device 100 attached to a circuit board 130, for example, by solder attachments of the bottoms of the conductive terminals 114 to conductive pads of the circuit board 130.

As shown in FIGS. 1 and 1A, the electronic device 100 has a package structure 108 with a generally rectangular shape that includes opposite first and second (e.g., bottom and top) sides 101 and 102, respectively, and lateral third, fourth, fifth, and sixth sides 103, 104, 105, and 106, respectively. In one example, the package structure 108 is a molded plastic structure. In another implementation, the package structure is or includes a ceramic structure (not shown). The electronic device 100 is shown in FIGS. 1 and 1A in an example position or orientation in a three-dimensional space with a first direction X, a perpendicular (orthogonal) second direction Y, and a third direction Z that is perpendicular (orthogonal) to the respective first and second directions X and Y, and structures or features along any two of these respective directions are orthogonal to one another. In the illustrated orientation, the respective first and second sides 101 and 102 are spaced apart from one another along the third direction Z, the respective third and fourth sides 103 and 104 are spaced apart from one another along the first direction X, and the respective fifth and sixth sides 105 and 106 are spaced apart from one another along the second direction Y.

The electronic device 100 includes a die attach pad 110 and a semiconductor die 112 that is attached to the die attach pad 110 in the package structure 108, for example, by solder or an adhesive (not shown). The electronic device 100 has conductive metal gull wing terminals 114 along each of the respective third and fourth sides 103 and 104. In other examples, the electronic device can have different types and forms of conductive terminals, such as J-type terminals, terminals of a ceramic or organic multilevel package substrate, through-hole terminals, etc. (not shown). In various implementations, conductive terminals can be located on one or more of the sides 101, 103, 104, 105, and 106, and the terminals can be flush with the associated side of the package structure 108 and/or can at least partially extend outward therefrom, and have a surface exposed outside the package structure 108 to allow soldering or socket connection to connect electrical circuitry of the semiconductor die 112 to a host printed circuit board (PCB, not shown).

The individual bond wires 115 are or include copper and are enclosed by the package structure 108. As shown in FIG. 1A, the individual bond wires 115 have a first end 117 and a second end 119. The first end 117 of each respective bond wire 115 in this example is connected to the semiconductor die 112, for example, to a conductive metal bond pad (not shown) by a first bond 118. In one example, the first bond 118 is a ball bond. The second end 119 of each respective bond wire 115 is connected to the nanotwin plated layer 116 of the corresponding conductive terminal 114 by a second bond 120. In one example, the second bond 120 is a stitch bond.

The conductive leads 114 in one example are or include copper with a nanotwin plated layer 116 extending along and contacting an outer surface of the respective conductive leads 114. In the illustrated example, the nanotwin plated layer 116 extends along the entire outer surface of the conductive leads 114 except the trimmed or cut ends of the conductive leads 114, which are or include bare copper. In another example, the nano twin plated layer 116 can extend on less than all of a side or sides of the associated conductive lead 114. For example, a plating mask (not shown) can be used during lead frame manufacturing to form the nano twin plated layer 116 on a portion of the top sides of the respective conductive leads 114 to which the second end 119 of a respective bond wire 115 is connected by a stitch bond 120.

The individual conductive terminals 114 in the illustrated example include outer portions that extend and are exposed outside the package structure 108. Interior portions of the respective conductive terminals 114 have the nanotwin plated layer 116 to which a stitch bond 120 connects the second end 119 of a respective bond wire 115, with the stitch bond 120 enclosed by the package structure 108. In the illustrated example, the outer portions of the respective conductive leads 114 also include portions of the nanotwin plated layer 116 exposed outside the package structure 108 except the trimmed or cut ends of the conductive leads 114 that have no plating 116 on the trimmed surfaces thereof. The nanotwin plated layer 116 in one example completely covers an outer surface of the interior portion of the conductive terminal 114 inside the package structure 108.

The conductive terminal 114 includes copper, and the nanotwin plated layer 116 includes copper. As further shown in FIG. 1B, the nano twin plated layer 116 includes copper grains with nano twinning in grain boundaries having a shifted segment of a crystal in which the crystal lattices on each edge are linked across a twin plane or twin boundary TB by mirror symmetry. The illustrated portion of the nanotwin plated layer 116 in FIG. 1B includes two instances of a first portion 121 (e.g., matrix grains or portions) on either side of a second portion 122 (e.g., a twin grain or portion), with a corresponding twin boundary TB between the first and second portions 121 and 122 in which crystal lattices on each side of the twin boundary TB are linked by mirrored symmetry.

FIG. 1C illustrates example crystalline structures and orientations a, b, and c of copper molecules M on either side of a twin boundary TB between matrix and twin grains 121 and 122 of the nanotwin plated layer 116. FIG. 1D shows example crystallographic 100, 110, and 111 copper molecule alignments and graphical alignment planes in an example three-dimensional space with axes a, b, and c corresponding to the orientations a, b, and c of the copper molecules M in FIG. 1C. FIG. 1E shows a crystalline structure view of a grain boundary GB between non-twinned copper grains (Grain 1 and Grain 2) of copper molecules M.

Coherent twinned boundaries TB line up to separate the internal grain into the two portions 121 and 122. The lattice compositions of the twin and matrix lamellae in one example maintain symmetry with regard to the twin boundary TB which follow an ordered arrangement of nano-scale twin lamellae within the nanotwin plated layer 116. Copper electrodeposited with a nano-twinned crystal orientation demonstrates superior mechanical and electrical properties through improved mechanical reliability and electromigration resistance.

The nanotwin plated layer 116 facilitates bonding of the copper bond wires 115 to the conductive leads 114 with enhanced bond strength. In the illustrated example, the second bond 120 is a stitch bond which facilitates cost effective fast wire bonding processing during fabrication of the electronic device 100, compared with lead frames plated with nickel-palladium (NiPd) or nickel-palladium-gold (NiPdAu) which are expensive, and the added processing can lengthen the lead frame manufacturing process. Moreover, the nanotwin plated layer 116 facilitates high strength stitch bonding to connect the bond wire 115 to the conductive lead 114 without added process complexity and costs associated with bonding using a patterned capillary tip.

In addition, the nanotwin plated layer 116 provides higher temperature higher wirebonding process temperature capabilities while mitigating oxidation and facilitates lower cost thermo-compression processing such as stitch bonding without the added expense of ultrasonic wirebonding. The bonding of the wire 115 to the nanotwin plated layer 116 enhances the mechanical stability and resistance to electromigration and facilitates mechanical strength of the second bond 120. Nanotwins of the plated layer 116 can provide mechanical stability of the interconnect structures and the nanotwin plated layer 116 in some examples exhibits improved hardness with a higher nanotwin density compared with bare unplated copper.

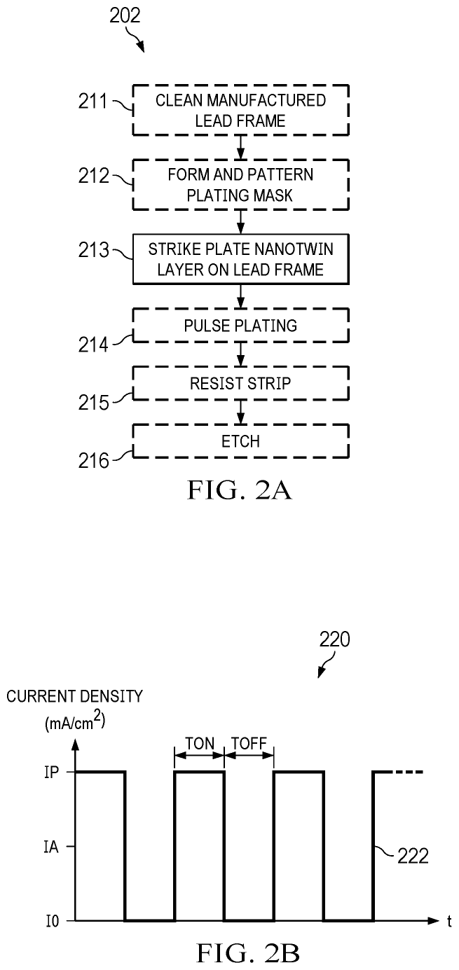

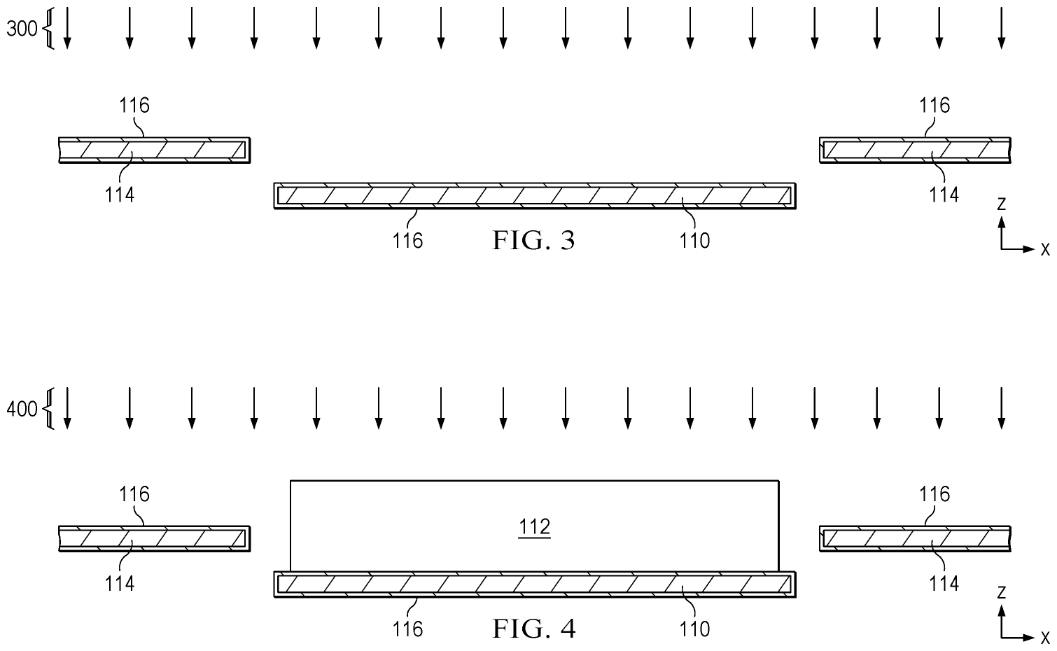

Referring also to FIGS. 2-7, FIG. 2 shows a method 200 for fabricating a lead frame with an included nano twin plating method 202 and for fabricating an electronic device with an included wirebonding process, and FIG. 2A shows an example implementation of the nano twin plating method 202 with optional pulsed plating. FIG. 2B is a graph of example pulsed nano twin plating process current density, and FIGS. 3-7 show the electronic device 100 undergoing fabrication processing according to the method 200 of FIGS. 2 and 2A.

At 202 in FIG. 1, a plating process is performed that forms the nanotwin plated layer 116 on all or a portion of a conductive terminal 114. Various implementations are possible, for example, using a specific nanotwin copper plating chemistry, pulse plating, strike plating, and/or combinations thereof or other suitable techniques and equipment. In one example, the plating process is performed during fabrication of a lead frame as a strip or panel array with multiple unit areas arranged in rows and columns. FIG. 3 shows one example, in which an electroplating process 300 is performed that forms the nanotwin plated layer 116 on all or a portion of conductive terminals 114 and a die attach pad 110 in an illustrated unit area of a lead frame panel array. In this example, the individual unit areas of the lead frame panel array include an instance of the illustrated die attach pad 110 and conductive features that are ultimately formed into the conductive leads 114 (e.g., leads), for example, connected together by tie bars (not shown) between adjacent unit areas which are subsequently trimmed or cut to separate the individual conductive terminals 114 from one another. In one implementation, the starting lead frame is or includes copper. In the illustrated example, the plating process 300 forms the nanotwin plated layer 116 as a nanotwin copper layer 116 on a copper conductive terminal 114. In one example, the plating process 300 forms the nanotwin plated layer 116 to a thickness of approximately 1 μm or more. Thinner nanotwin layers can cause weakness in a finished wire bond or may inhibit bonding. Larger plated layer thicknesses can be used with a possible tradeoff in terms of productivity with respect to increased plating time and added material cost.

In the illustrated implementation, moreover, the plating process 300 forms the nanotwin plated layer 116 directly on exposed surfaces of the copper features of the lead frame including exposed surfaces of the die attach pad 110 and the prospective leads 114. In another implementation, a plating mask (not shown) can be formed to cover select portions of the lead frame surface or surfaces in order to selectively allow electroplating to form the nanotwin plated layer 116 on particular locations of the lead frame. For example, a plating mask can include openings to facilitate electroplating of the nanotwin plated layer 116 on all or portions of the upper or top surface or sides of the conductive leads 114 to which a bond wire is to be subsequently bonded during electronic device fabrication.

FIG. 2A shows one example implementation of a plating process at 202 in FIG. 2, which includes optionally cleaning a manufactured lead frame 211, for example, after stamping and etching processing. In another implementation, the cleaning at 211 can be omitted. At 212 in FIG. 2A, an optional plating mask is formed and patterned. In another implementation, no plating mask is used and the processing at 212 can be omitted, for example, to provide a lower cost lead frame. At 213 in FIG. 2A, the example plating processing 202 includes strike plating the nanotwin plated layer 116 on the lead frame, either on select portions not covered by the optional plating mask, if formed at 212, or on all exposed sides and surfaces of the lead frame. Strike plating can be used in one example, although not required of all possible implementations. Any suitable electroplating processes and equipment can be used that provides a nanotwin plated layer 116 on all or a portion of one or more sides and surfaces of the lead frame. In the illustrated example, the plating process 300 forms the nanotwin plated layer 116 as a nanotwin copper layer 116 on a copper conductive terminal 114.

Referring also to FIG. 2B, in one implementation, the nanotwin plated layer 116 is formed using pulsed plating, illustrated as a separate step 214 and FIG. 2A, although a single pulsed electroplating process 300 can be used as shown in FIG. 3. In other implementations, multiple plating steps are used to form the nanotwin plated layer 116 at 202 in FIG. 2, for example, including strike plating an initial thin portion of the nanotwin plated layer 116 followed by pulse electroplating (e.g., immersed in a solution or a dry electroplating tool) to form the remainder of the nanotwin plated layer 116. In the illustrated example, the plating process 300 is a pulsed plating process that includes pulsing a plating current density at 214 in FIG. 2A.

A graph 220 in FIG. 2B shows one example with a current density curve 222 illustrating pulsed control of the electroplating current of the process 300. The electroplating current is controlled, for example, by suitable switching control of the plating current density between a maximum plating current density labeled “IP” and an off state of approximately zero current density labeled “I/O” as a function of time. The example of FIG. 2B includes controlling a duty cycle of the pulsed plating process 300, for example, to approximately 50% or other suitable duty cycle expressed as a ratio of an on-time labeled “TON” divided by an off-time labeled “TOFF”.

The duty cycle in various implementations can be controlled as an approximately constant duty cycle or the duty cycle may be varied, for example, to facilitate formation of a <111> oriented nanotwin plated layer 116 with a high fraction of nano-twinning in one example. In one implementation, the plating process 300 completely covers an outer surface of the conductive terminal 114 and other exposed features of the lead frame panel array with the nanotwin plated layer 116. The process 300 forms the nanotwin plated layer 116 to any suitable thickness to facilitate consistent electrical properties and bondability for subsequent formation of the second bond 120 (FIGS. 1 and 1A above) during wire bonding. At 215 in FIG. 2A, any previously formed resist or plating mask is removed, and the lead frame panel array may be etched at 216, for example, to remove any residue from the nanotwin plated layer 116.

The method 200 continues at 204 in FIG. 2 with die attach processing. FIG. 4 shows one example, in which a die attach process 400 is performed that attaches the semiconductor die 112 to the die attach pad 110. Any suitable attachment process and materials can be used, for example, an adhesive (not shown) may be dispensed, printed, or otherwise formed on the top side of the die attach pad 110 (e.g., directly on the top side of the die attach pad 110 and/or on any included nanotwin plated layer 116 that was previously plated on the top side of the die attach pad 110). The semiconductor die 112 is positioned on the adhesive, for example, using automated pick and place equipment (not shown), and the attachment process 400 can include adhesive curing, for example, by thermal heating, UV exposure, etc.

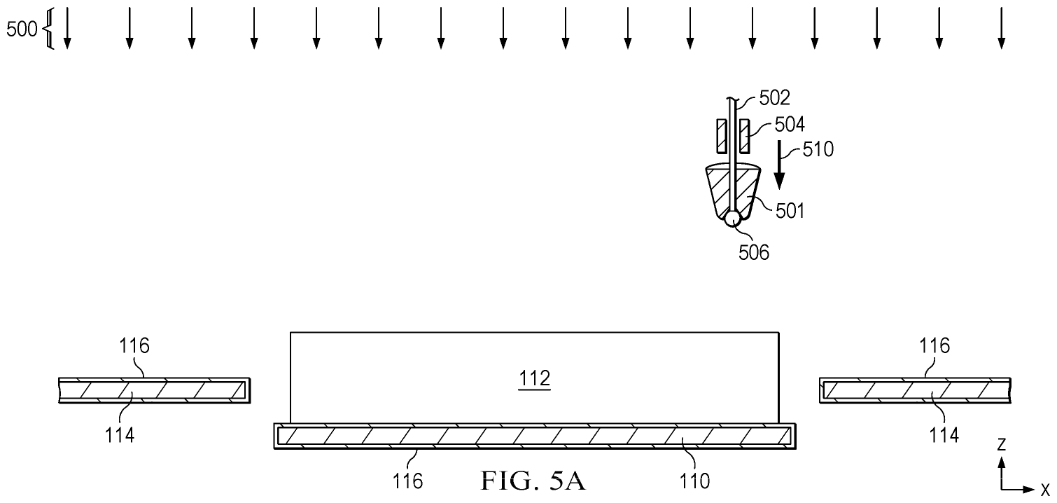

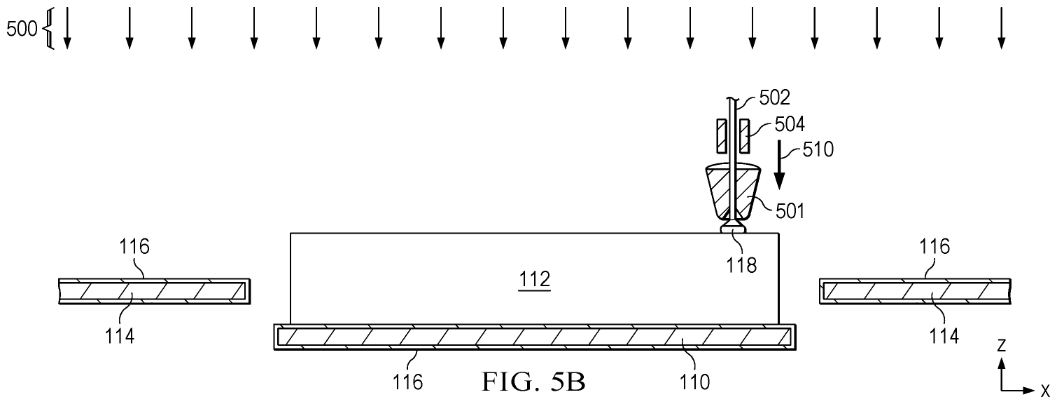

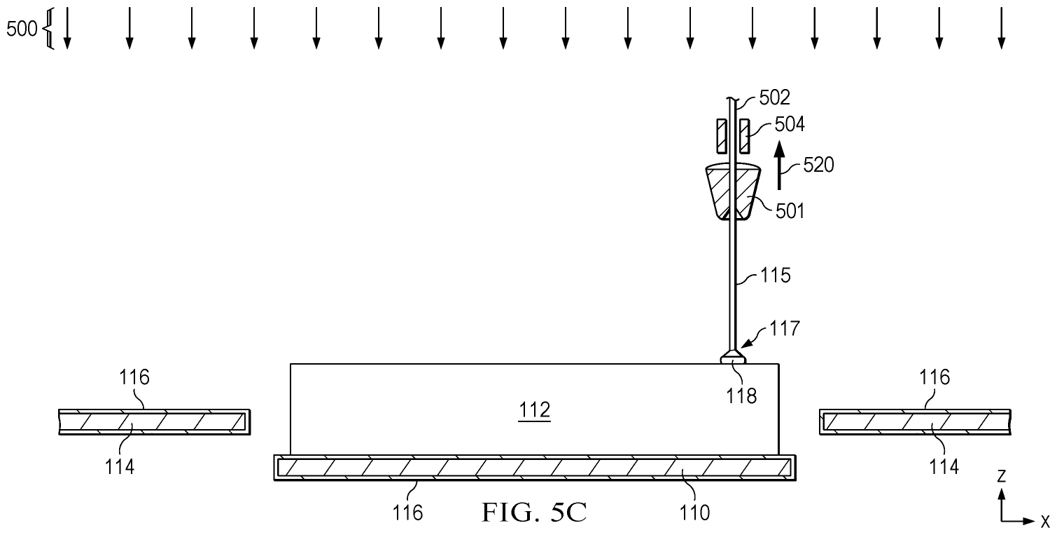

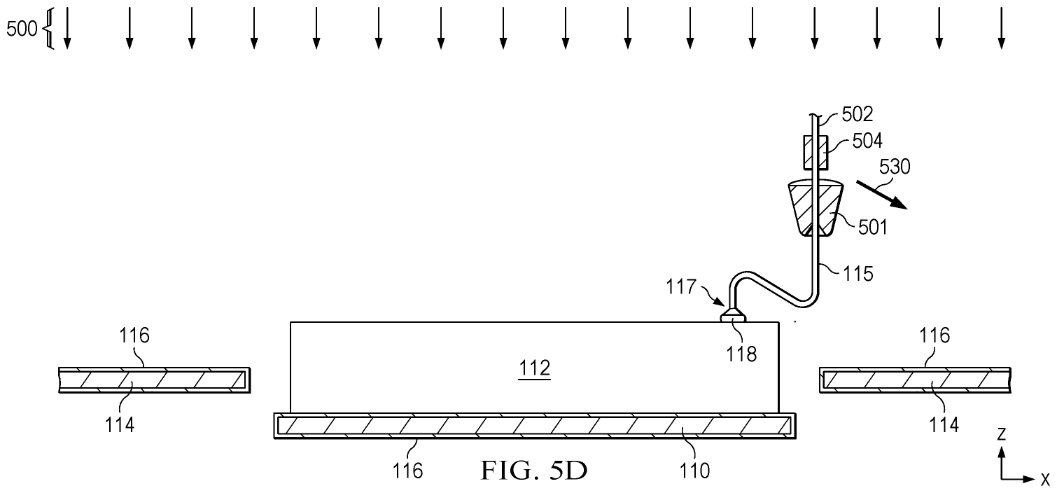

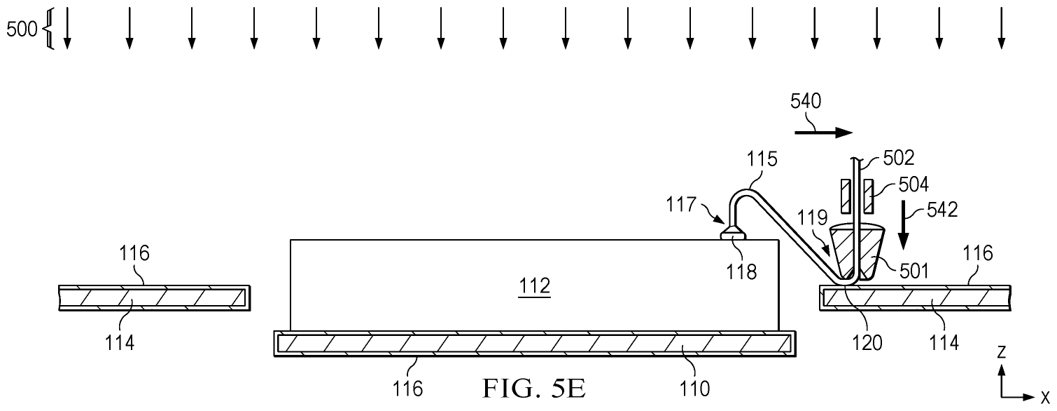

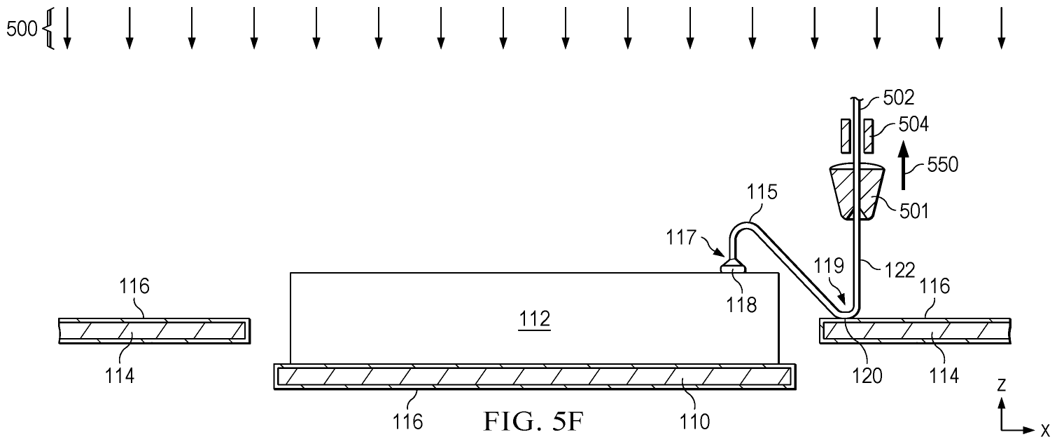

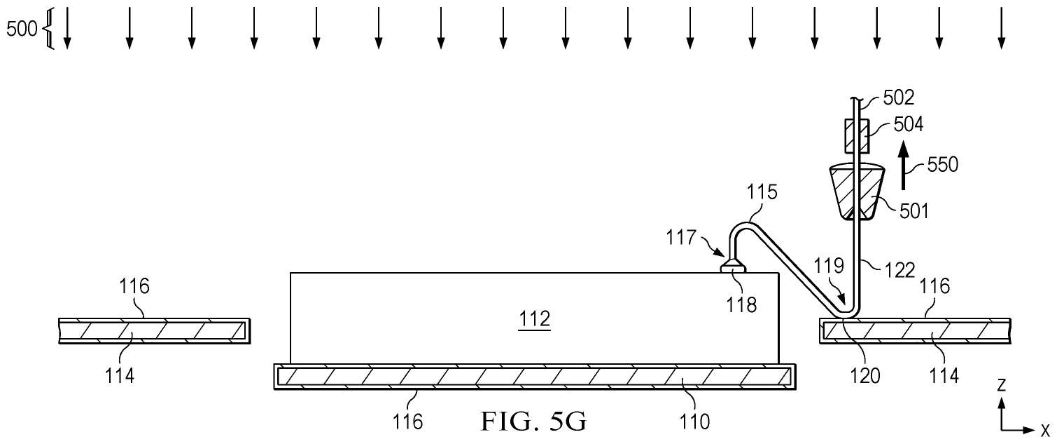

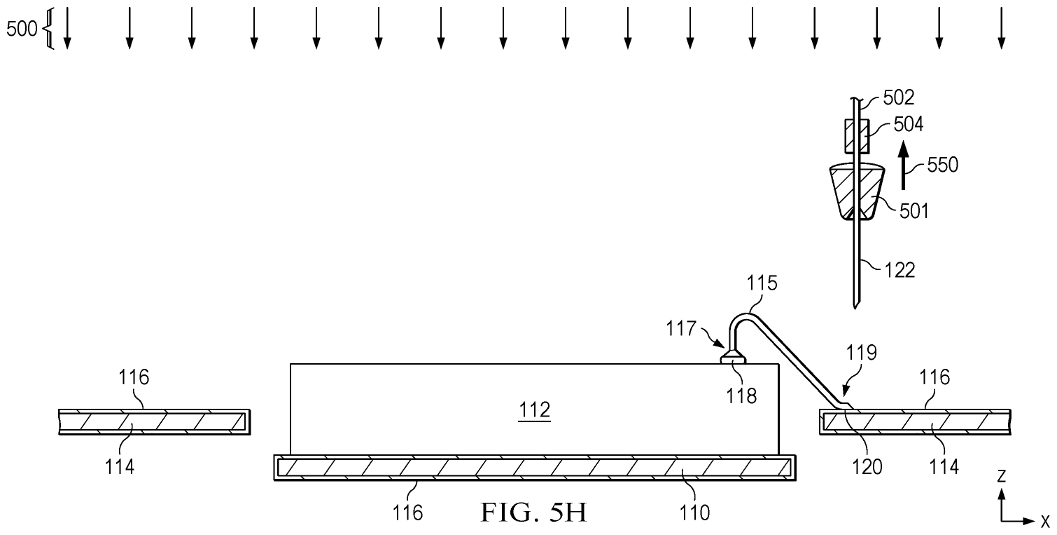

The method 200 continues with wire bonding at 206 in FIG. 2 for creating one or more bond wire interconnections in the electronic device 100. FIGS. 5A-5I show one example, in which a wire bonding process 500 is performed that forms one or more instances of a bond wire 115 (e.g., FIGS. 1 and 1A above) having a first end 117 connected to the semiconductor die 112 by a first bond 118, and a second end 119 connected to the nanotwin plated layer 116 of an associated conductive terminal 114 by a second bond 120. In the illustrated example, the wirebonding process 500 forms the first bond 118 as a ball bond and forms the second bond 120 as a stitch bond 120. The example wirebonding process 500 uses a wirebonding tool with a nozzle 501 with a concentric channel through with a conductive wire 502 can be translated along the third direction Z and a clamp 504 to automatically control and selectively inhibit translation of the wire 502.

The wirebonding at 206 can include any type or form of bond wire bonds and techniques, for example, one or more of ball bonding, stitch bonding, wedge bonding, compliant bonding, etc., with or without externally applied heat, using any suitable conductive wire 502, for example, that is or includes copper of any suitable wire diameter. In one implementation, the wirebonding at 206 includes attaching the wire 115 at both ends using one or more of downward pressure, ultrasonic energy, heat, to make a weld, where externally applied heat can be optionally used to make the metal softer, for example, in a low-cost thermo-compression wirebonding process. In another implementation, the wirebonding can include a thermos-sonic bonding implementation that combines external heat with ultrasonic energy during one or more bonding steps.

The wirebonding at 202 includes forming a first bond in creating a bond wire. FIG. 5A shows one example, in which a molten metal ball is formed by a flame off process. A position control apparatus (not shown) moves the nozzle 501 close to an electronic flame source (not shown). In one example, the system energizes an electronic flame source (not shown) to form a flame or arc to melt the end of the conductive wire 502 to form a ball 506 that is suspended by the remainder of the wire 502 while the clamp 504 remains closed as shown in FIG. 5A.

The first bond 118 is formed in FIG. 5B, for example, to connect the wire 502 to a bond pad or other conductive feature of the semiconductor die 112. In one example, the first bond 118 is formed as a ball bond. In one example, the clamp 504 is opened as shown in FIG. 5B, and the position control apparatus moves the nozzle 501 downward in FIG. 5 along the direction 510 to move the ball 506 toward the bond pad (not shown) of the semiconductor die 112 with the clamp 504 open. The downward movement of the nozzle 501 continues with the ball 506 touching the top side of the bond pad and the ball 506 progressively collapses and laterally spreads to form the first bond 118 (e.g., a ball bond) while the clamp 504 remains open. The ball bond 118 in this example couples the first end of the prospective bond wire 115 to the semiconductor die 112. In one example, heat is applied during formation of the first bond 118. In this or another example, the position control apparatus can optionally vibrate the nozzle 501 at high (e.g., ultrasonic) frequencies to bond the ball 506 to the top side of the bond pad to form the first bond 118 as shown in FIG. 5B, including lateral movement of the nozzle 501 back and forth along the first X direction, or in a circular pattern in an X-Y plane, to form the ball bond 118.

As further shown in FIG. 5C, the bond wire formation in this example includes retracting the nozzle with the clamp 504 open. The position control apparatus extends the first bond wire portion 116 upward along the indicated direction 520. The wire bonding process 500 continues with formation of a main loop of the prospective bond wire 115 to a prospective lead or other conductive terminal 114 of the lead frame panel. In this example, the nozzle 501 is moved laterally away from the semiconductor die bond pad along the first direction X with the clamp 504 initially open. The clamp 504 is then closed as shown in FIG. 5D and the position control apparatus moves the nozzle 501 toward the conductive terminal 114 along the direction 530 in FIG. 5D while the clamp 504 remains closed.

The wirebonding process 500 in this example continues in FIG. 5E with coupling the second end 119 of the prospective bond wire 115 to the conductive terminal 114 by the second bond 120. In one example, the second bond 120 is a stitch bond. In another example, the second bond 120 is a wedge bond. The wire 502 is then separated after forming the second bond 120. As shown in FIG. 5E, the position control apparatus moves the nozzle 501 further laterally along the direction of the arrow 540 until the center of the bond wire 502 in the nozzle 501 is positioned above a first portion of the conductive terminal 114 and then downward along the direction 542 to cause the second end 119 of the first portion 116 of the prospective bond wire 115 to contact the conductive terminal 114 as shown in FIG. 5E. In various implementations, the coupling of the second end 119 of the first portion 116 and the first end 123 of the second portion 122 to the conductive terminal 114 includes forming the second bond 120 as a stitch bond or a wedge bond, for example, by thermos-compression using applied downward force along the direction 542. In this or another example, the position control apparatus can optionally vibrate the nozzle at high (e.g., ultrasonic) frequencies to bond the second end 119 of the prospective bond wire 115 to the first portion of the top of the conductive terminal 114, for example, including lateral movement of the nozzle 501 back and forth along the X direction, or in a circular pattern in an X-Y plane, to form a stitch bond 120.

The wirebonding process 500 continues in FIG. 5F, with retraction of the nozzle 501 to a suitable tail height, in which the position control apparatus moves the nozzle 501 upward along the third direction Z as shown by the direction arrow 550 to a suitable tail height with the clamp 504 open. The clamp 504 is then closed as shown in FIG. 5G and the position control apparatus moves the nozzle 501 upward along the third direction Z as shown by the direction arrow 550. As shown in FIG. 5H, the wirebonding process 500 continues with further nozzle retraction along the direction 550 to tear off the tail of the wire 502 with the clamp remaining closed. This separates or breaks the wire 502 in the nozzle 501 from the second end 119 of the completed bond wire 115 to complete the second bond 120.

As shown in FIG. 5I, the wire bonding process 500 can be repeated in order to form further bond wires 115 for interconnection of various bond pads of the semiconductor die 112 to corresponding conductive terminals 114 and/or to form other bond wire interconnections according to a particular design of an electronic device.

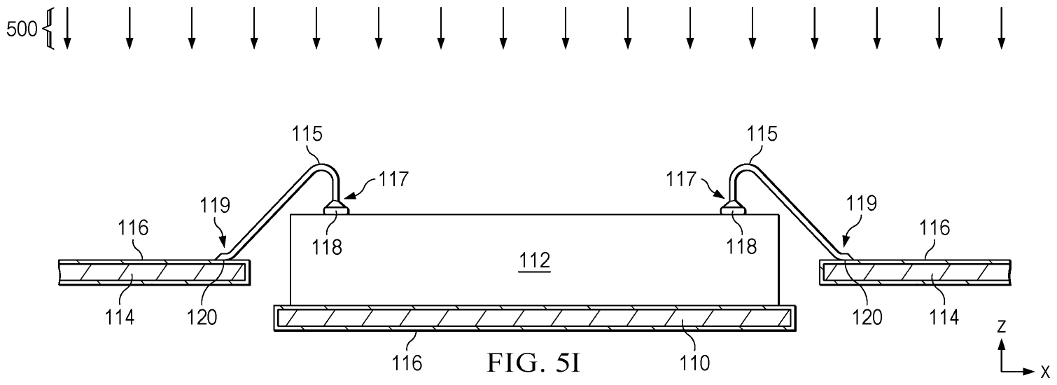

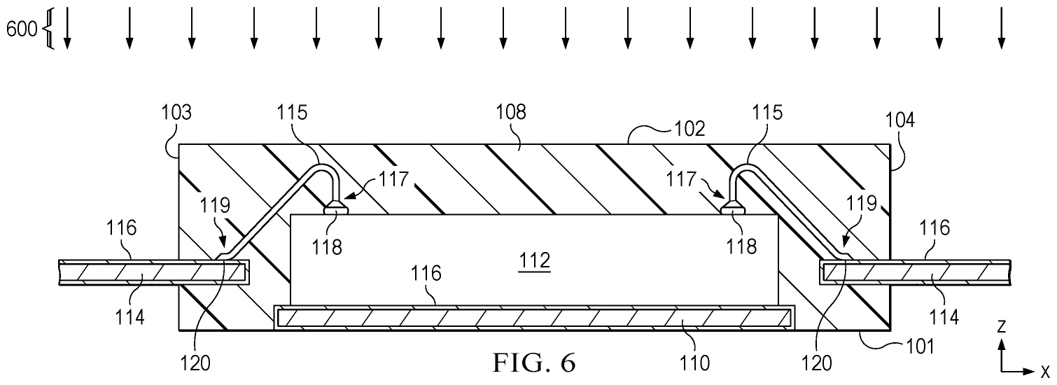

Once the wire bonding is completed at 206 and FIG. 2, the example electronic device fabrication process 200 continues at 208 with package molding. FIG. 6 shows one example, in which a molding process 600 is performed that forms the molded package structure 108 which encloses the semiconductor die 112, the bond wires 115 and interior portions of the conductive terminals 114.

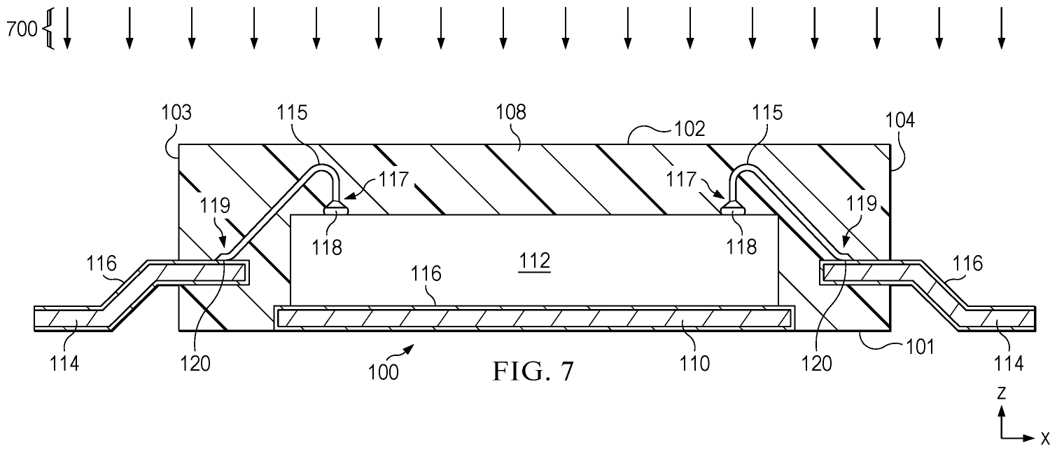

At 210 in FIG. 2, lead trimming and forming operations are performed along with package separation and other back end processing to provide multiple finished packaged electronic device products, such as the device 100 shown in FIGS. 1 and 1A above. FIG. 7 shows one example, in which lead trimming and forming processing 700 is performed that trims or otherwise separates the conductive terminals 114 from the starting lead frame panel and bends or otherwise forms the trimmed conductive terminals 114 into the desired gull wing shapes. The lead trimming in the illustrated example cuts through adjacent conductive lead portions of the starting lead frame panel array across boundaries between adjacent unit areas and can leave unplated trimmed ends of the finished conductive terminals 114 of the finished electronic device 100 as shown in FIG. 7. As discussed above, and other implementations, other portions of the conductive terminals 114 (and/or all or portions of the die attach pad 110) can have bare copper surfaces without the plated layer 116, for example, by selective plating using a plating mask during fabrication of the starting lead frame.

Modifications are possible in the described examples, and other implementations are possible, within the scope of the claims.

What is claimed is:

1. An electronic device, comprising:
a package structure;
a conductive terminal exposed outside the package structure and having a nanotwin plated layer;
a semiconductor die in the package structure; and
a bond wire enclosed by the package structure and having a first end and a second end, the first end connected to the semiconductor die by a first bond, and the second end connected to the nanotwin plated layer by a second bond.

2. The electronic device of claim 1, wherein the conductive terminal includes copper, and the nanotwin plated layer includes copper.

3. The electronic device of claim 2, wherein the second bond is a stich bond.

4. The electronic device of claim 3, wherein the nanotwin plated layer includes a first portion, a second portion, and a twin boundary between the first and second portions in which crystal lattices on each side of the twin boundary are linked by mirrored symmetry.

5. The electronic device of claim 1, wherein the second bond is a stich bond.

6. The electronic device of claim 1, wherein the nanotwin plated layer includes a first portion, a second portion, and a twin boundary between the first and second portions in which crystal lattices on each side of the twin boundary are linked by mirrored symmetry.

7. The electronic device of claim 1, wherein the nanotwin plated layer completely covers an outer surface of the conductive terminal inside the package structure.

8. A system, comprising a circuit board and an electronic device attached to the circuit board, the electronic device comprising:
a package structure;
a conductive terminal exposed outside the package structure and having a nanotwin plated layer, the conductive terminal soldered to a conductive feature of the circuit board;
a semiconductor die in the package structure; and
a bond wire enclosed by the package structure and having a first end and a second end, the first end connected to the semiconductor die by a first bond, and the second end connected to the nanotwin plated layer by a second bond.

9. The system of claim 8, wherein the conductive terminal includes copper, and the nanotwin plated layer includes copper.

10. The system of claim 8, wherein the second bond is a stich bond.

11. The system of claim 8, wherein the nanotwin plated layer includes a first portion, a second portion, and a twin boundary between the first and second portions in which crystal lattices on each side of the twin boundary are linked by mirrored symmetry.

12. The system of claim 8, wherein the nanotwin plated layer completely covers an outer surface of the conductive terminal inside the package structure.

13. A method of fabricating an electronic device, the method comprising:
performing a plating process that forms a nanotwin plated layer on a conductive terminal; and
performing a wirebonding process that forms a bond wire having a first end connected to a semiconductor die by a first bond, and a second end connected to the nanotwin plated layer by a second bond.

14. The method of claim 13, wherein the plating process forms the nanotwin plated layer as a nanotwin copper layer on a copper conductive terminal.

15. The method of claim 14, wherein the plating process is a pulsed plating process that includes pulsing a plating current density.

16. The method of claim 15, comprising controlling a duty cycle of the pulsed plating process.

17. The method of claim 14, wherein the wherein the plating process completely covers an outer surface of the conductive terminal with the nanotwin plated layer.

18. The method of claim 13, wherein the plating process is a pulsed plating process that includes pulsing a plating current density.

19. The method of claim 18, comprising controlling a duty cycle of the pulsed plating process.

20. The method of claim 13, wherein the wirebonding process forms the second bond as a stitch bond.

21. A lead frame, comprising:
a conductive terminal; and
a nanotwin plated layer on an outer surface of the conductive terminal.

22. The lead frame of claim 21, wherein the conductive terminal includes copper, and the nanotwin plated layer includes copper.

23. The lead frame of claim 21, wherein the nanotwin plated layer includes a first portion, a second portion, and a twin boundary between the first and second portions in which crystal lattices on each side of the twin boundary are linked by mirrored symmetry.

24. The lead frame of claim 21, wherein the nanotwin plated layer completely covers an outer surface of the conductive terminal.
